(19) United States
(12) Patent Application Publication
(10) Pub. No.: US 2013/0247961 A1
(43) Pub. Date: Sep. 26, 2013

(54) SOLAR COLLECTOR HAVING A CONCENTRATOR ARRANGEMENT FORMED FROM SEVERAL SECTIONS

(71) Applicant: Andrea Pedretti, Bellinzona (CH)

(72) Inventor: Andrea Pedretti, Bellinzona (CH)

(73) Assignee: Airlight Energy IP SA, Biasca (SE)

(21) Appl. No.: 13/880,580

(22) PCT Filed: Oct. 24, 2011
(86) PCT No.: PCT/CH2011/000257

§ 371 Date: Jun. 14, 2013

(30) Foreign Application Priority Data
Oct. 24, 2010 (CH) 1744/10
Oct. 24, 2010 (CH) 1745/10
Oct. 24, 2010 (CH) 1746/10
Oct. 25, 2010 (CH) 1774/10
Oct. 25, 2010 (CH) 1775/10
Oct. 25, 2010 (CH) 1776/10

(51) Int. Cl. F24J 2/42; H01L 31/058

(52) U.S. Cl. CPC F24J 2/42; H01L 31/058
USPC 136/248; 126/651

(57) ABSTRACT

Due to the further concentrators of a second concentrator arrangement in a linear concentrator configured as a trough concentrator, the concentrated radiation is concentrated in focal point areas, with the consequence that higher concentration of the radiation and thus higher temperatures are achievable in the absorber pipe. In order to lower the exponentially increasing heat losses in the absorber pipe (due to the higher temperatures), an absorber arrangement is provided in synergy, comprising rows of individual thermal openings, wherein these rows lie adjacently to each other.

The present invention relates to a solar collector according to the preamble of claim 1.

Radiation collectors or concentrators of the kind mentioned are used in solar power plants.

Because it has not been possible up to now to overcome the disadvantages of photovoltaics this technology cannot be used for generating solar current at anywhere near reasonable cost. Solar thermal power plants on the other hand have been generating current on an industrial scale for some time now, at prices which are close to today's common commercial prices for conventionally produced current.

In solar thermal power plants the sun's radiation is mirrored by collectors with the aid of a concentrator and selectively focussed onto a location in which, as a result, high temperatures are created. The concentrated heat can be dissipated and used for the operation of thermal power engines such as turbines which in turn drive the current-producing generators.

Today there are three known forms of solar thermal power plant: dish-sterling-systems, solar tower power plant systems and parabolic trough systems.

The dish-sterling-systems, being small units in a range of up to 50 kW per module, have generally not been accepted.

Solar tower power plant systems comprise a central absorber mounted in a raised position (on the “tower”) for mirroring the sunlight to it through hundreds and thousands of individual mirrors, so that the radiation energy of the sun can be concentrated in the absorber via the many mirrors or concentrators thereby hoping to achieve temperatures of up to 1300° C., which is favourable for the efficiency of the downstream thermal machines (as a rule a steam or fluid turbine power plant for power generation). The “Solar Two” plant in California has an output of several MW. The PS20 plant in Spain has an output of 20 MW. Nevertheless solar tower power plants have not become widespread to any degree either (despite the advantage of achievable high temperatures).

Parabolic trough power plants, however, have become widespread and include a large number of collectors which comprise long concentrators with a small transverse dimension and therefore do not have a focal point but a focal line. These line concentrators have today a length of 20 m to 150 m. Along the focal line extends an absorber pipe for the concentrated heat (up to 500° C.) which transports the heat to the power plant. Possible transport media are for example thermal oil, molten salts or overheated water vapour.

Conventional absorber pipes are of complicated and expensive construction in order to minimise heat losses as much as possible. Since the heat-transporting medium circulates inside the pipe, the solar radiation concentrated by the concentrator first heats up the pipe, and the pipe then heats up the medium so that the (of necessity) hot absorber pipe (about 500° C.) emits heat commensurate with its temperature. The heat emitted via the line network for the heat-transporting medium may reach 100 W/m, and the line length in a large-scale plant may be up to 100 km so that the heat losses via the line network are of considerable importance to the overall efficiency of the power plant, as is the proportion of heat losses from the absorber pipes.

In consequence, the absorber lines are of increasingly complicated construction in order to avoid these energy losses. As such conventional absorber lines are widely configured as a glass-covered metallic pipe with a vacuum present between glass and metal pipe. The metal pipe carries the heat-transporting medium and is, on its external surface, provided with a coating which improves the absorption of radiated light in the visible range, but has a low emission rate for wavelengths in the infrared range. The enveloping glass pipe protects the metal pipe against cooling through wind and acts as an additional barrier against heat emission. The disadvantage is that the enveloping glass wall also partially reflects or absorbs any incident solar radiation which has led to a coating being applied to the glass, in order to reduce reflection.

In order to lower the considerable amount of money spent on cleaning such absorber lines and in order to protect the glass against mechanical damage, the absorber line may be additionally provided with a (non-insulating or hardly insulating) mechanical protective pipe surrounding it, which albeit has to be provided with an opening for the incident sun rays but in other respects reliably protects the absorber line.

Such constructions are cumbersome and correspondingly expensive, both as regards manufacture and maintenance.

The 9 SEGS parabolic trough power plants in Southern California together produce an output of approx. 350 MW. The “Nevada Solar One” power plant linked into the network in 2007 comprises trough collectors with 182,400 curved mirrors which are arranged over an area of 140 hectares and which produce 65 MW. Andasol 3 in Spain has been under construction since September 2009 and is to become operative in 2011 which means that the output of the Andasol plants 1 to 3 will be up to 50 MW in total.

The peak efficiency of the overall Andasol installation (Andasol 1 to 3) is expected to be in the region of 20%, the annual average efficiency in the region of 15%.

As already mentioned one essential parameter for the efficiency of a solar power plant is the temperature of the transport medium heated by the collectors, the heat gained from the collector is dissipated via this transport medium and utilised for example for conversion into electric current: the higher the temperature the higher the efficiency achieved during conversion. The temperature which can be realised in the transport medium again depends upon the concentration of the reflected solar radiation through the concentrator. A concentration of 50 means that within the focal range of the concentrator an energy density per square meter is achieved, which corresponds to 50 times the energy irradiated by the sun onto one square meter of earth surface.

The theoretically possible maximum concentration depends upon the earth-sun geometry, i.e. upon the angle of aperture of the sun disc as observed from the earth. From this 0.27° angle of aperture it follows that the theoretically possible maximum concentration factor for trough collectors is 213.

Even for mirrors manufactured at a great deal of expense and thus mirrors regarded as too expensive in terms of industrial use and which in cross-section are quite close to a parable thus generating a focal line area of minimum diameter, it still is not possible to even approximately achieve this maximum concentration of 213. A reliably achievable concentration of about 50 to 60, however, is realistic, allowing temperatures of nearly 500° C. as mentioned above in the absorber pipe of a parabolic trough power plant.

In order to construct a trough collector with as near a parabolic shape as possible at reasonable cost, the applicant, in the WO 2010/037243, has proposed a trough collector, which comprises a pressure cell with a flexible concentrator arranged inside it. This concentrator has different curvatures in different areas and is very close to the desired parabolic shape. This makes it possible to achieve a temperature of nearly 500° C. in the absorber pipe at reasonable cost for the concentrator, but what is not possible is a once more increased process temperature in the absorber pipe.

It is therefore the requirement of the present invention to provide a trough collector for the production of heat, also on an industrial scale, which exhibits a higher efficiency and also permits to generate even higher temperatures in the transport medium.

This requirement is met by a solar collector with the characteristics of claim 1.

Due to the fact that the second concentrator arrangement causes the reflected solar radiation to be reflected, not any longer in a focal line area, but in at least one focal point area, a concentration is achieved in the one-dimensional trough collector, which is two-dimensional, i.e. a concentration over the length of the collector in a focal line and then over its width in at least one focal point area. This has the effect of an increase in the theoretically maximum possible concentration to over 40,000. It must be said that even here there is no way of even approximately achieving this maximum possible concentration. But even a small realisation of this enormous potential allows the temperatures in the transport medium to be increased as specified in the requirement thus improving the efficiency of the power plant (or even of a unit generating a minimum amount of heat).

Due to the fact that the at least one concentrator of the second concentrator arrangement is continuously aligned with respect to the current first radiation path, losses in the second concentrator arrangement, which are due to the oblique angle of incident solar radiation corresponding to the time of day, can be avoided thereby ensuring a consistently high degree of efficiency of the arrangement.

Due to the fact that several rows of further concentrators and several adjacently arranged rows of thermal openings are provided in the absorber arrangement (in contrast to, for example, a single row of the same number of thermal openings), an improved power absorption/improved efficiency of the overall arrangement is achieved.

Further, the focal point areas of the further concentrators of the second concentrator arrangement remain stationary and thus in situ on the absorber arrangement. This in turn, despite variations in the incident solar radiation, allows to reduce the thermal opening of the absorber pipe to the cross-section of the entering radiation path, which has the effect of reducing relevant heat losses of the absorber pipe and increasing the efficiency of the solar power plant.

The present invention thus permits, in addition to the specified requirement, to use an absorber arrangement/an absorber pipe, in which the area of the thermal opening is divided into individual small openings and thus is reduced to an essentially smaller overall area. This, at the same time, significantly reduces the heat losses of the respective absorber pipe.

This leads to a synergy with the radiation concentrated in focal point areas according to the present invention: on the one hand, the possible temperature in the absorber pipe is increased, and on the other, the heat losses from the absorber pipe are reduced which is of particular importance here since the heat losses are mostly caused by heat emission, which increases with the fourth power of the temperature. Then—last but not least—the efficiency of the collector according to the invention is further increased by the layout of the arrangement which provides for adjacently extending rows of focal point areas with adjacently extending rows of associated thermal openings in the absorber arrangement/the absorber pipe, which layout causes an increased power absorption of the arrangement.

Due to the fact that a number of spaced-apart thermal openings are provided a larger area of the absorber pipe can be insulated, with the effect that in operation its heat emission is reduced. Since heat emission grows with the fourth power of the temperature, this is particularly advantageous in the case of the solar collector according to the invention for generating higher temperatures.

Special embodiments of the present invention will now be described in detail with reference to the figures, in which

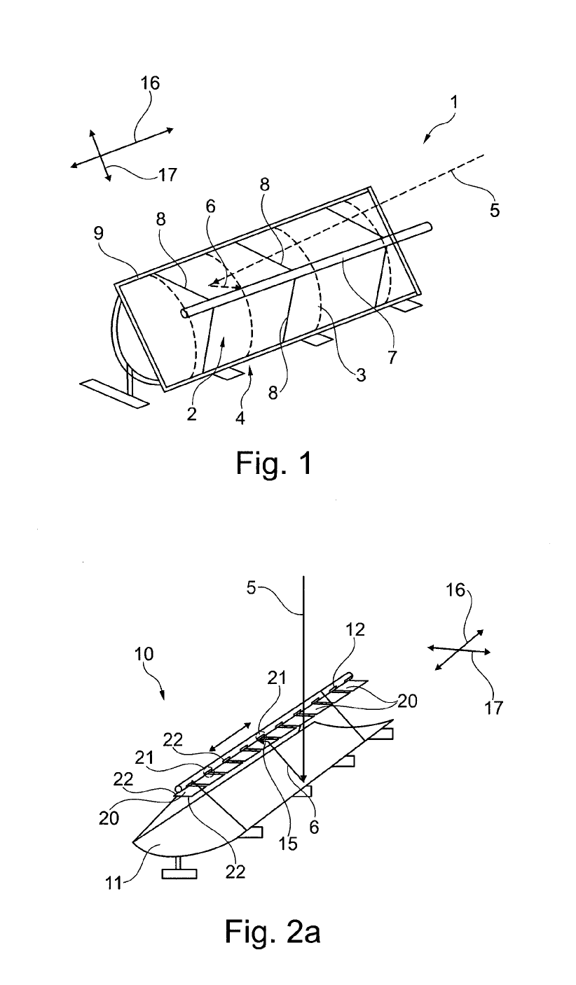

FIG. 1 schematically shows a conventional trough collector such as used in solar power plants,

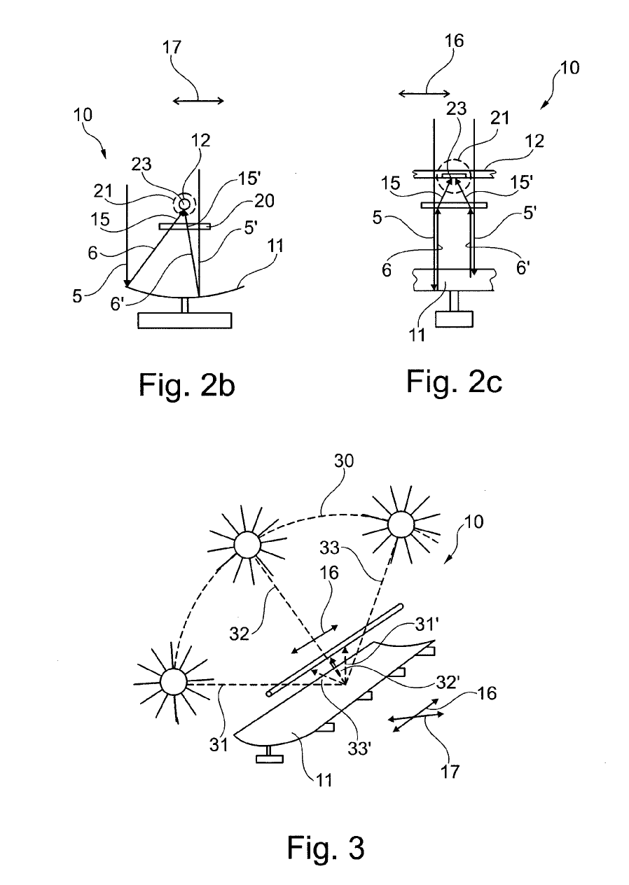

FIG. 2a schematically shows the construction of a trough collector according to the present invention,

FIG. 2b shows a cross-section through a trough collector of FIG. 2a,

FIG. 2c shows a longitudinal section through a trough collector of FIG. 2a,

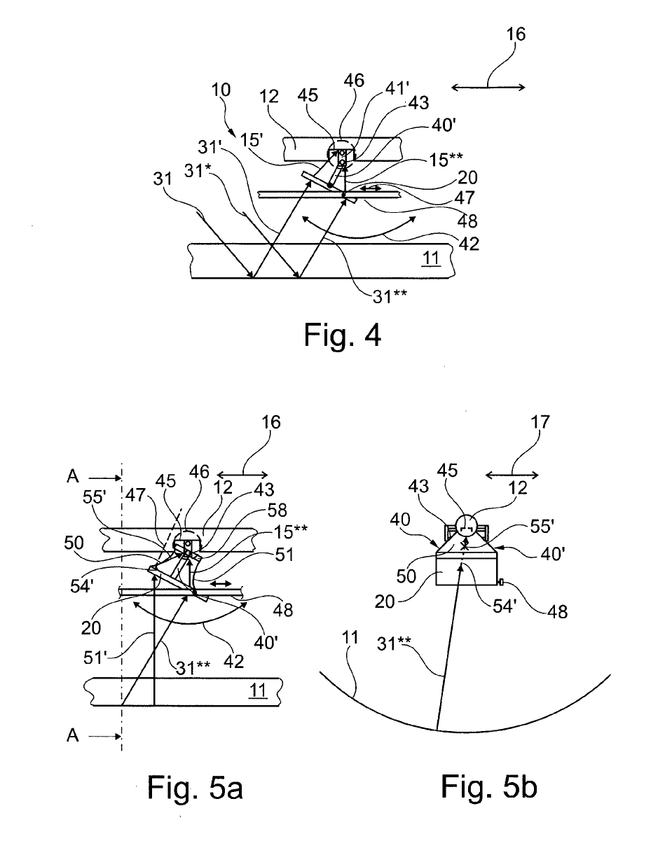

FIG. 3 schematically shows the direction of the incident solar radiation over the course of the day,

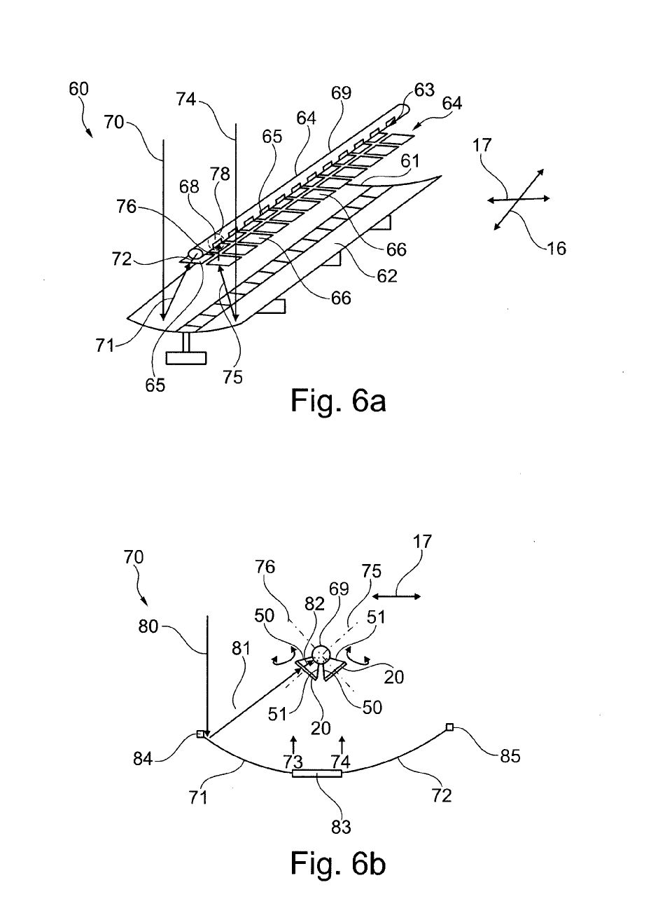

FIG. 4 shows a preferred embodiment of the present invention,

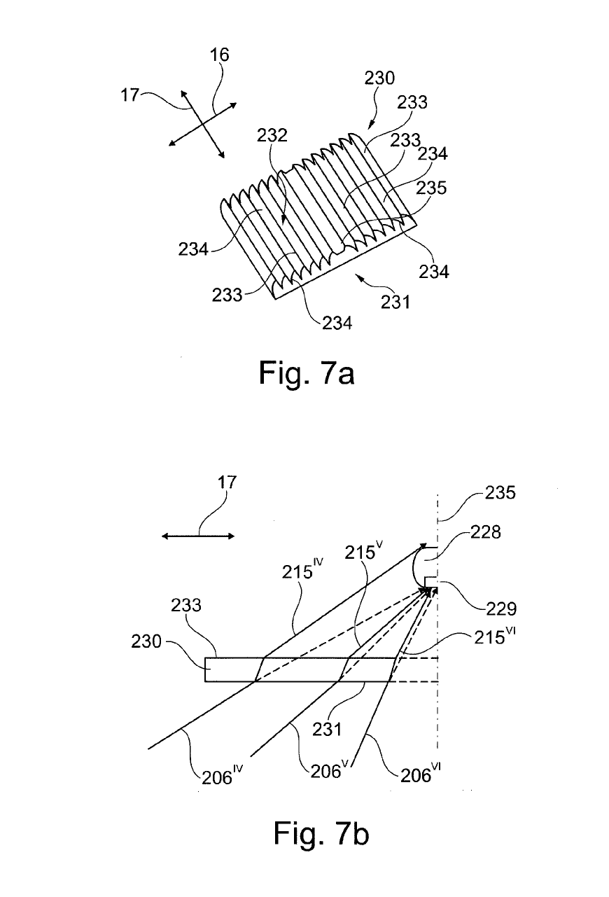

FIG. 5a shows a particularly preferred modification of the embodiment shown in FIG. 4 in a longitudinal view;

FIG. 5b shows the embodiment of FIG. 5a in a cross-sectional view,

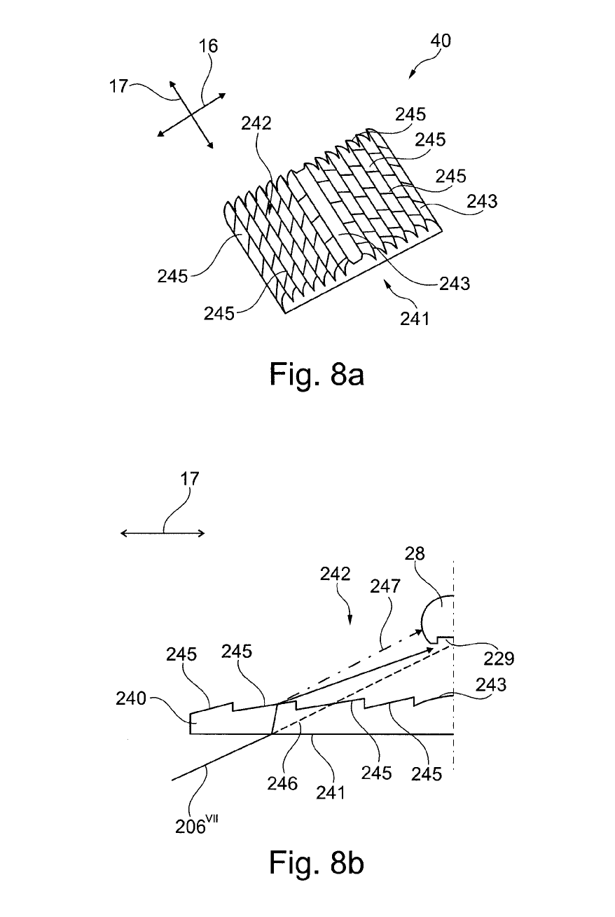

FIG. 6a shows a view of a further embodiment of the present invention,

FIG. 6b shows a cross-sectional view of the embodiment of FIG. 6a,

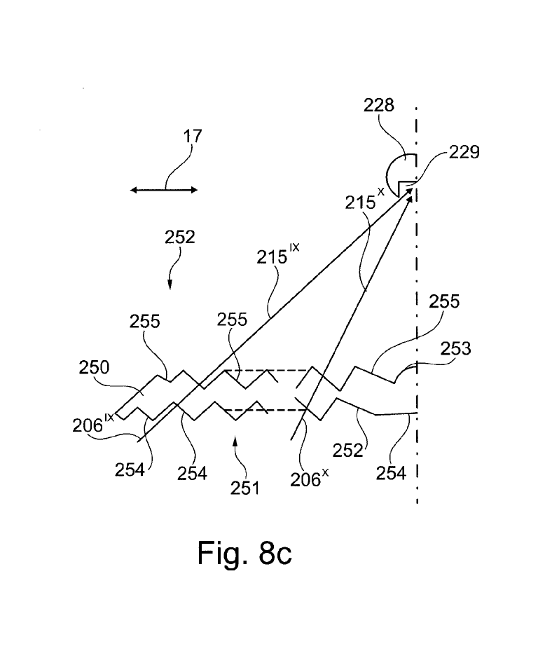

FIG. 7a shows a first embodiment of the optical element of the further concentrators,

FIG. 7b shows the optical element of FIG. 7a in cross-section, wherein the geometry of the radiation passing through the element is shown,

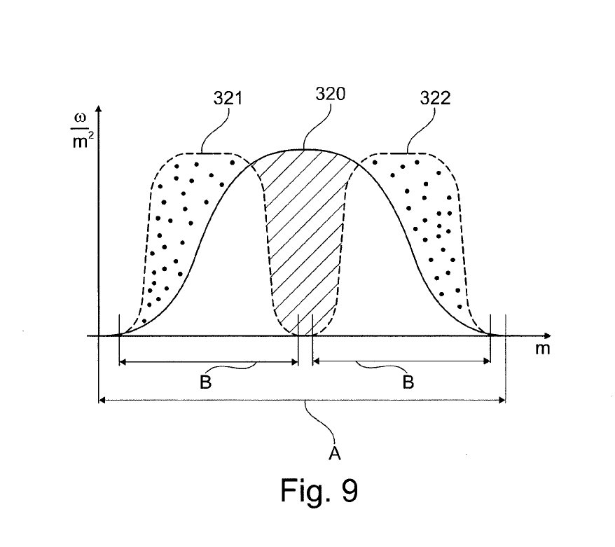

FIG. 8a shows a second embodiment of the optical element of the further concentrators,

FIG. 8b shows the optical element of FIG. 8a in cross-section, again with the geometry of the passing-through radiation,

FIG. 8c shows a third embodiment of the optical element of the further concentrators,

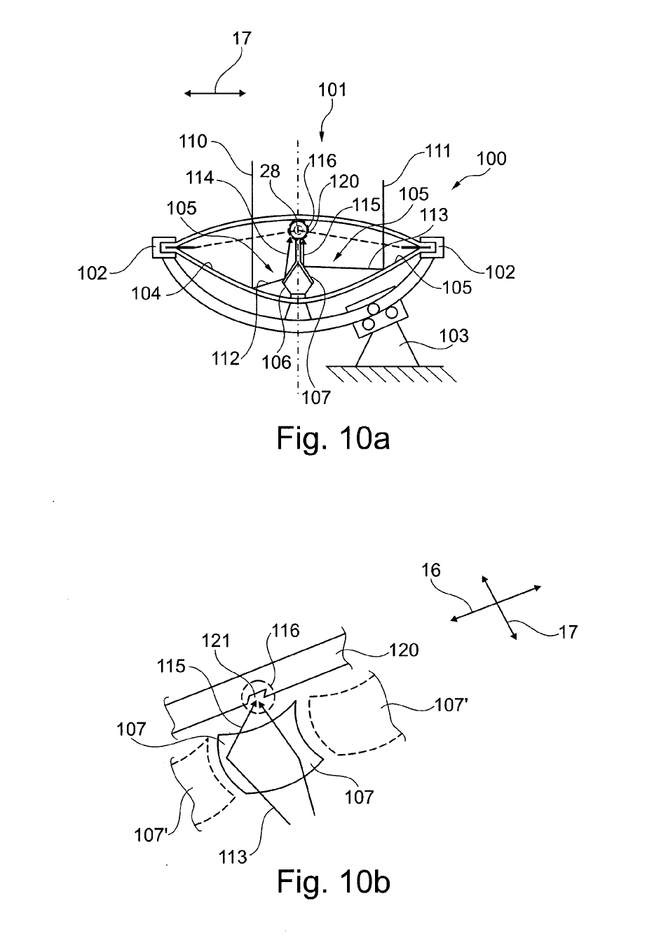

FIG. 9 shows a comparison between the power absorption of a conventional arrangement and the arrangement according to the invention, which comprises several rows of adjacently arranged thermal openings.

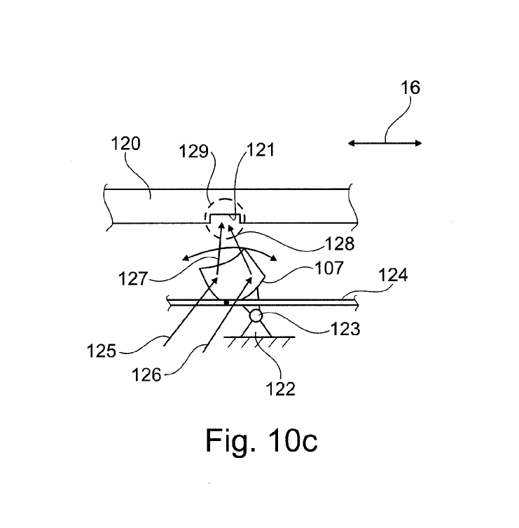

FIG. 10a shows a cross-section through an additional embodiment of the invention, and

FIG. 10b shows a detail view of the embodiment of FIG. 10a.

FIG. 1 shows a trough collector 1 of the conventional type with a pressure cell 2, which has the shape of a cushion and which is formed by an upper flexible membrane 3 and a lower flexible membrane 4 hidden in the figure.

The membrane 3 is permeable to sun rays 5 which are incident upon a concentrator membrane (concentrator 10, FIG. 2a) inside the pressure cell 2 and are reflected by the former as rays 6, in direction of an absorber pipe 7, in which a heat-transporting medium circulates which dissipates the heat concentrated by the collector. The absorber pipe 7 is held by supports 8 in the focal line area of the concentrator membrane (concentrator 10, FIG. 2a).

The pressure cell 2 is arranged in a frame 9 which is pivotably mounted on a stand in the known manner, according to the daily position of the sun.

Such sun collectors are for example described in the WO 2010/037243 and the WO 2008/037108. The documents are expressly included by reference in the present description.

Although the present invention is preferably used in such a solar collector shaped as a trough collector, i.e. with a pressure cell and a concentrator membrane positioned in the pressure cell, it is in no way limited to this, but can also be used, for example, in trough collectors, the concentrators of which are not configured as flexible mirrors. Collectors with non-flexible mirrors are, for example, used in the above-mentioned power plants.

In the figures described hereunder the components of the trough collector, which are not relevant to the invention, have been omitted, wherein it should be mentioned once more that such omitted components are configured according to the above-described state of the art (collectors with pressure cell or collectors with non-flexible mirrors) and can easily be determined by the expert to suit the actual application.

FIG. 2a shows a possible embodiment of the further concentrators according to the invention. A collector 10 configured in principle like collector 1 in FIG. 1 comprises a concentrator 11 and an absorber pipe 12 mounted on supports 8. Sun rays 5 are incident upon the concentrator 11 and reflected as rays 6 by the same. Due to this actual configuration of the concentrator 11 a first radiation path for reflected radiation is created which is represented by rays 6.

The concentrator 11 is a linear concentrator, because it is curved in one direction only, with the advantage that compared to the parabolic concentrators curved in two directions, it can be manufactured in a simpler way and with a large surface without giving rise to prohibitive constructional marginal conditions for the frame structure and the continuously necessary alignment during the day according to the position of the sun.

For orientation in the figure the longitudinal direction is indicated by arrow 16 and the transverse direction is indicated by arrow 17. Accordingly the concentrator 11 is curved in transverse direction 17 whilst in longitudinal direction 16 is it is not.

The radiation path of the concentrator 11, of necessity has to have a focal line area, since on the one hand, due to the angle of aperture of the sun, its rays 5 are not incident in parallel making it impossible to have a concentration in a geometrically accurate focal line, and also because it is not possible to produce an exact parable-shaped curvature of the concentrator at reasonable cost for a focal line theoretically approximated as much as possible.

The concentrator 11 is part of a first concentrator arrangement of the collector 10, which here is composed of the pressure cell (not shown in order to make the drawing clearer), the organs for maintaining and controlling pressure and the frame, in which the concentrator 11 is positioned. As also mentioned the omitted elements are known to the expert.

Optical elements 20 which are transparent to concentrated radiation and configured as plates in the figure, are arranged in the first radiation path of the concentrator 11 (and thus in the radiation path of the first concentrator arrangement), so that the radiation path passes through them. These optical elements 20 break the radiation 6 incident upon them (and reflected by the concentrator 11) in such a way that the radiation 6 downstream of the optical elements 20 is concentrated as radiation 15 in a focal point area. In other words, the second radiation path represented by the radiation 15 of each of the optical elements 20, comprises a focal point area 21. The figure shows a number of optical elements 20 corresponding to the length of the solar collector and, as an example, the focal point areas for two optical elements 20.

The optical elements 20 are part of a second concentrator arrangement disposed in the first radiation path upstream of the focal line area and form further concentrators in the second concentrator arrangement. Here the second concentrator arrangement includes, for example, carriers 22 fixed to the absorber pipe 12 and on which the optical elements 20 are held in position.

The absorber arrangement implemented here as an absorber pipe 12 is located at the location of the focal point areas 21 and has a number of thermal openings 23 through which the concentrated radiation 15 can pass into the interior of the absorber pipe 12. A thermal opening permits heat from the concentrated radiation to pass through, but need not necessarily be configured as a mechanical opening. For example, a thermal opening may be configured, relative to a non-transparent insulation, as a glass disc possibly coated for damping the retro-radiation. But it is nevertheless a fact that in the end good insulation cannot be achieved at the location of the thermal opening, and corresponding relevant heat losses therefore have to be accepted.

It should be mentioned at this point that photovoltaic cells may be arranged in a thermal opening of the absorber arrangement, which directly generate electric current in which case a heat-transporting medium (description of FIG. 1) would be omitted. For simplicity's sake, but non-limiting, the remaining description refers to an absorber arrangement in which a heat-transporting medium circulates.

Preferably an external absorber pipe is used, i.e. an absorber pipe with totally enclosed non-transparent heat insulation on its outside, the thermal openings of which are configured as physical openings in this external insulation (but which can, of course, be closed by a glass disc, for example).

FIG. 2b shows a section in transverse direction (arrow 17) through the collector 10 of FIG. 2a with a view of the radiation path/the first and second radiation paths of the two concentrator arrangements projected into this cross-section plane. As mentioned above, in order to aid understanding of the invention, non-essential elements of the trough collector 20 are known to the expert and have therefore been omitted in the figure.

In particular it can be seen that the first radiation path of the first concentrator arrangement (concentrator 11) represented here by the two reflected rays 6, 6′ converges towards a focal line area 21 at the location of the absorber pipe 12. The radiation 6 passes through the optical element 20, wherein its second radiation path represented here by the two rays 15, 15′ converges towards the focal point area 21.

Concentration of the first concentrator arrangement is effected in transverse direction (arrow 17).

In the preferred embodiment shown the focal point areas 21 of optical elements 20 lie in the focal line area of the concentrator 11, i.e. in the focal line area of the first concentrator arrangement. For the view shown in FIG. 2b upon the cross-section plane (but not in longitudinal direction, see FIG. 2c below) this means moreover that the reflected radiation 6 is not broken by the optical element 20, i.e. that it extends essentially in a straight. Mainly because, when a ray 6, 6′ passes through the optical element 20, the radiation path 15, 15′ may be slightly offset relative to the path 6, 6′, which, however, is not relevant here.

Again, in order to aid understanding of the figure, non-essential elements have been omitted, such as the carriers 22 (FIG. 2a) for the optical elements 20.

FIG. 2c shows a section through the collector 10 of FIG. 2a in longitudinal direction (arrow 16) with a view of the radiation path/the first and second radiation paths of the first and second concentrator arrangements, projected into this longitudinal plane. However, only part of the longitudinal section along the length of one of the optical elements 20 is shown.

Assuming a direction of view from right to left (FIG. 2b) FIG. 2c shows the view upon the left half of the concentrator 11 (FIG. 2b).

In particular it can be seen that the first radiation path of the first concentrator arrangement (concentrator 11) shown here by the reflected rays 6, 6′, progresses towards a focal line area at the location of the absorber pipe 23. The radiation 6 to 6′ passes through the optical element 20, is broken by it in longitudinal direction 16, wherein the second radiation path of the optical elements 20 (represented by rays 15, 15′) respectively converges towards a focal point area 21.

The concentration of the second concentrator arrangement is effected in longitudinal direction (arrow 16).

As a result the second concentrator arrangement comprises at least one optical element 20 (i.e. at least one further concentrator) with a second radiation path, wherein at least one focal point area 21 is created by the at least one optical element 20. It should be mentioned at this point that the arrangement according to the invention can be implemented for small or very small applications with only one optical element 20, or for industrial use in collectors with very large dimensions with dozens or hundreds of optical elements 20.

FIGS. 2b and 2c also show that the optical element 20 in the embodiment depicted is configured as a linear concentrator with a direction of concentration which extends transversely or vertically to the direction of concentration of the linear concentrator of the first concentrator arrangement.

This also means that the optically effective surfaces (which cause breaking of the light rays) are aligned relative to the first radiation path of the first concentrator arrangement (here of concentrator 11) such that the path of each individual ray projected onto a plane perpendicular to the focal line area (as shown in FIG. 2b) is a straight, but that it is broken in a plane within the focal line area (shown in FIG. 2c) in direction of the focal point area 21.

Preferably the optical elements comprise a Fresnel structure which permits configuration of the same with a plate-shaped body shown in FIGS. 2a-2c. For example the underside of the plate-shaped body may be planar and the topside may be structured with parallel Fresnel steps, wherein the steps in transverse direction 17 extend in parallel with each other so that the focal point area lies above the centre of the plate-shaped body.

The layout of such a Fresnel lens 30 can be easily accomplished in practice by an expert. Alternatively each optical element 20 may be configured as a collecting lens which extends in transverse direction below the absorber pipe 12 and creates refraction as shown in FIGS. 2b and 2c. Optical elements 20 configured in this way can be produced by moulding, for example, wherein a metal mould is manufactured and a suitable plastic material (or even glass) is moulded.

FIG. 3 shows the collector 10 and the orbit 30 of the sun from morning till evening. Depicted are the sun rays 31, 32 and 33 which are incident upon the concentrator 11 at the same location and reflected by the same in the first radiation path as rays 31′, 32′ and 33′ depending upon the time of day. In other words, the incidence of the sun rays upon the concentrator 11, i.e. the first concentrator arrangement, changes throughout the day within an operating range so that its first radiation path continuously changes as the day progresses, wherein the current first radiation path is represented in the morning by the ray 31′, at midday by the ray 32′ and in the evening by the ray 33′. Correspondingly the focal line area of the concentrator 11 is displaced only in its longitudinal axis (direction 16), but not transversely thereto. Even so, this is a disadvantage because the rays 31′ and 33′ are obliquely incident upon the optical element 20 (FIGS. 2a and 2c) and therefore partially enter into the element and are broken as per the invention, but are also partially reflected from the surface of the optical element which is detrimental to the efficiency of the solar collector 10 since the reflected rays do not reach the focal point area. This effect is near zero in the case of ray 32′ and increases with an increase in the obliqueness of rays 31′ and 33′ incident upon the lower surface of the optical element 20.

FIG. 4 shows an arrangement according to the invention which increases the average efficiency of the second concentrator arrangement. The figure, analogous to FIG. 2c, shows a section through the collector 20 in longitudinal direction (arrow 16), wherein only a part of the longitudinal section is shown in order to explain in detail the relationships by way of a random optical element 20 of the collector 10 (FIG. 2a).

The optical element 20 is pivotably mounted via a carrier pair 40, 40′ (of which only one carrier 40′, the front one in the image, is visible) on carriers in turn fixedly arranged on the absorber pipe 12 (of which only one carrier 41′, the front one in the image, is visible). This allows the element to be pivoted in direction of the double arrow 42, respectively in such a way, that it is aligned with the current radiation path of the first concentrator arrangement, i.e. so that it extends perpendicularly to the current first radiation path. In the figure the current radiation path is represented by the rays 31′ and 31**. The second radiation path is represented by the rays 15′ and 15**.

The pivotal movement is triggered by a lever 48 movable in direction of the double arrow 47, which lever is connected with the optical element 20 (and all other optical elements of collector 10). A control of the collector (not shown in the figure to aid its understanding) can activate a drive (not shown) for lever 48 so that the alignment of the optical element 20 during the day is always correct. The feed range of the lever 48 defines an alignment range for the optical elements 20, and this alignment range corresponds to the time-of-day radiation conditions prevalent at the location of the collector 10 (FIG. 3).

The carrier pairs with carriers 40, 40′ and 41, 41′ as well as the lever 47 with associated drive and its control represent means for aligning the at least one concentrator (optical elements 20 in the depicted embodiment) of the second concentrator arrangement relative to a current first radiation path of the first concentrator arrangement, according to the time of day.

The preferred embodiment shown in the figure has the advantage that due to the carrier pair with carrier 41, the pivotal axis 43 is placed in the area of the thermal opening 45 so that, in consequence, the focal point area 46 indicated as a broken line is fixedly held in a fixed position across the entire alignment range of the optical element 20 (or alignment range of the at least one concentrator of the second concentrator arrangement).

Since the absorber pipe 12 is fixedly arranged relative to the concentrator 11, this also applies to the focal point area 45. In other words, based on the shown arrangement, the focal point area 45 of the concentrator of the second concentrator arrangement (optical element 20) is fixedly held relative to a fixed position in relation to a concentrator section of the first concentrator arrangement (here the section of concentrator 11 shown in the figure).

This arrangement makes it possible to reduce the thermal openings 45 so as to match the extension of the fixed focal point area 46, i.e. to match those dimensions which in total result from the changing alignment of the radiation (FIG. 3). If the optical element 20 were not aligned according to the invention the thermal opening would have to have a length which corresponds to the displacement of the focal point area over the time of day. For a long exposure to the sun during the day this could even lead to individual thermal openings touching each other, leading to a thermal opening for the absorber pipe, which would extend continuously along its whole length. This would result in a corresponding heat loss which however can be avoided according to the invention.

FIG. 5a shows a further embodiment according to the present invention, wherein the embodiment according to FIG. 4 is supplemented by two delimiting mirrors 50, 51. A preferred arrangement of these mirrors will be known to the expert as a compound parabolic concentrator. According to the knowledge of the applicant compound parabolic concentrators have up to now not been used in solar collectors with linear concentrators. In a compound parabolic concentrator the mirrors 50, 51 exhibit a profile corresponding to a branch of a parable, wherein the focal point of this parable lies on the lower edge of the opposite mirror. The delimiting mirrors 50, 51 are fastened, on the one hand, to the optical element 20 and to an upper bracket 58 on the other, fixed relative to the optical element 20 and pivotably arranged with the same.

These delimiting mirrors 50, 51 have the effect of correcting any scattering of the radiation reflected in the first radiation path. The scattering is due, on the one hand, to the angle of aperture of the sun with the effect that the solar radiation is not incident as parallel radiation, and on the other, to the concentrator 11 itself the surface of which cannot be manufactured so as to be geometrically ideal at reasonable cost, which can result in a further interference with the path of the radiation. Also errors in the optical element 20 can cause interference in the second radiation path which is corrected by the delimiting mirrors 50, 51.

In the figure a ray 31** is shown in the first radiation path and a ray 15** is shown in the second radiation path. Let it be assumed that ray 31** is the reflected ray of a ray originating from the centre of the sun, and that the concentrator 11 is configured so as to be geometrically ideal at the location of the reflection. Accordingly ray 15** extends ideally through the centre of the focal point area 46.

The figure also shows a ray 53′ in the first radiation path and a ray 54′ in the second radiation path. Let it be assumed here that ray 53′ is the reflected ray of a ray originating from the edge of the sun, and/or that the concentrator 11 comprises a geometric deviation at the location of the reflection. Accordingly rays 31** and 53′ are not parallel, and furthermore ray 54′ is not aligned with the focal point area 46 despite refraction in the optical element 20 (or because of an error in the optical element 20), but would miss it as indicated by the broken line 47.

Ray 54′ accordingly impacts upon the delimiting mirror 50 and is reflected by the same as ray 55′ into the focal point area 46.

This reflection at the delimiting mirror 50 has the effect that all radiation impacting on it in terms of its angle of acceptance is concentrated upon the focal point area 46. In other words, the delimiting mirrors 50, 51 represent a third concentrator arrangement, with a third radiation path, the focal point area of which lies at the location of the focal point area 46 of the second radiation path.

FIG. 5b shows a view of the arrangement of FIG. 5a in a section along the plane AA of FIG. 2a. What is seen is the underside of the optical element 20, the rear of the delimiting mirror 50, wherein the cross indicated here marks the point of impact of the ray 54′.

At this point let it be added that the figure shows the use of the delimiting mirrors 50, 51 in longitudinal section through the collector 10, i.e. that their surface extends in direction 17, i.e. crosswise. The delimiting mirrors 50, 51 may, however, also be aligned lengthwise, in direction 16 so that the path of the radiation is corrected, for example, by non-parallel incident radiation from the sun, due to errors in the curvature of the concentrator 11 in transverse direction (direction 17) or due to errors effective in transverse direction in the optical element 20 by further concentration in a third radiation path.

In a further preferred embodiment delimiting mirrors are provided for correcting the radiation path in longitudinal and in transverse direction.

FIG. 6a shows a collector 60 configured according to the invention, the first concentrator arrangement of which comprises several adjacently and longitudinally extending concentrator sections 61, 62. At this point it should be mentioned that the first concentrator arrangement may comprise, not two but for example four, six, eight or more such concentrator sections.

A further embodiment of a solar collector of the kind shown in the FIG. 6a includes a trough collector with a concentrator of 50 m length, wherein the concentrator comprises two parallel sections of 4 m width each, which are curved such that their focal line area is at a distance of 3 m. The optical elements may be configured, not as plate-shaped bodies, but as half shells curved in transverse direction (with a suitable Fresnel structure), and would then have a radius of curvature of 200 mm and a length of 200 mm. Accordingly approx. 250 optical elements are provided along the length of the absorber pipe, wherein the absorber pipe (FIG. 10) has 250 thermal openings.

Each concentrator section 61, 62 is associated with a row 63, 64 of optical elements 65, 66, wherein again each optical element 65, 66 is associated with a separate thermal operating 67, 68 in the absorber pipe 69. Again, for better understanding of the figure, the carriers for the optical elements 65, 66 and other non-essential elements for understanding the invention, have been omitted. At this point it should be mentioned that optical elements 65, 66 adjacent in transverse direction may all be associated with one thermal opening.

A sun ray 70 in the concentrator section 61 is reflected as ray 71 (first radiation path of concentrator section 61), broken by the optical element 65 and directed as ray 72 (second radiation path of optical element 65) into a focal point area not visible in the figure at the location of the hidden thermal opening 67.

Similarly a sun ray 74 is reflected in the concentrator section 62 as ray 75 (first radiation path of the concentrator section 62), broken by the optical element 66 and directed as ray 76 (second radiation path of optical element 66) into a focal point area 78 at the location of the thermal opening 68.

This arrangement has the advantage that the transverse extension (direction 17) of the individual concentrator sections 61, 62 is smaller than would be the case with a single concentrator so that relative to a wider concentrator, smaller focal point areas are achievable (angle of aperture of the sun). This again leads to smaller thermal openings 67, 68 the overall surface of which is smaller than the surface of the thermal openings for only one but distinctly wider concentrator. The same applies in longitudinal direction: instead of the thermal opening (no matter whether this is physically formed or not, see above) conventionally extending uninterruptedly along the length of the absorber pipe 69, spaced-apart thermal openings arranged along the length of the absorber pipe 69 are now possible, which in total occupy a smaller surface than the continuous thermal opening according to the state of the art.

Naturally, all optical elements 65, 66 are pivotably arranged, according to the invention, on the absorber pipe 69 as shown by way of example in FIGS. 4 to 5b. Further the optical elements 65, 66 are configured as Fresnel lenses, as described above.

FIG. 6b shows a slightly modified collector 70 relative to FIG. 6a, again with two concentrator sections 71, 72 and two rows 73, 74 of optical elements 20. As mentioned above it is of course possible to provide, for example, six concentrator sections and six rows of optical elements 20. The optical elements 20 of each row 73, 74 are aligned with the respectively associated concentrator section 71, 72 and thus obliquely positioned so that they can be pivoted in an oblique plane indicated by the chain-dotted lines 75, 76, according to the invention. Due to having the optical elements 20 aligned in this way the efficiency of the arrangement is further improved. The figure also shows a sun ray 80, a reflected ray 81 representing the first radiation path of the concentrator section 71 and a ray 82 representing a correctly extending second radiation path (which thus passes the delimiting mirror by). Furthermore the figure shows a preferably walkable strip 83 as well as lateral frame parts 84 and which have the concentrator sections 71, 72 positioned between them. Preferably the width of the strip 83 is chosen such that only the strip is shadowed by the two rows 73, 74 of the optical elements 20.

In a further preferred embodiment the lens 230 comprising a Fresnel structure is further improved as per FIG. 7a in order to minimise errors through aberration:

FIG. 7b shows a section in transverse direction 17 through the Fresnel lens 230 when fitted, the section extending along one of the steps 233. In this section, in order to aid understanding of the figure, only that half of the Fresnel lens 230 is shown, which is situated left of the chain-dotted line of symmetry 35, together with the radiation path extending through it. Sun rays 206^{iv} to 206^{vi} reflected by the first concentrator arrangement (here concentrator 11/sections 71, 72) are incident upon the optically effective lower surface 231, are broken at this in direction of the plumb line 236, then progress through the body of the Fresnel lens 230 as far as the optically effective upper surface 232 and leave the same as rays 215^{iv} to 215^{vi}, wherein they are broken away from the plumb line at the upper surface 232. Since the steps 233 and the flanks 234 extend in transverse direction 17, it follows that the twice broken rays 215^{iv} to 215^{vi} are slightly offset in parallel, wherein the offset for the external rays is larger than for the internal rays possibly causing the focal point area to be disadvantageously enlarged depending upon the actual case. This is shown qualitatively (and exaggeratedly) by the broken-line continuations of rays 26^{iv} to 26^{v}: if the rays 26^{iv} to 26^{v} had not been broken twice, they would be quite well concentrated upon the thermal opening 229 of absorber pipe 228. The described parallel offset is the result of the rays being broken so that only some of the rays 215^{iv} to 215^{vi} reach the thermal opening 229, which cannot be optimal.

FIG. 8a shows an embodiment which is optimised in this respect. Shown is an optical element configured as a Fresnel grid lens 240, the lower optically effective surface 241 of which is planar, and the upper optically effective surface 242 of which, apart from the central zone 243, comprises a Fresnel grid structure. The basic structure of the Fresnel grid lens 240 corresponds to the structure of the optical element 230. The deviation in relation to the optical element 230 lies in the configuration of the flanks 244 which in turn are divided into facets 245, wherein each facet 245, when fitted, is differently inclined in transverse direction 217. How, is shown in FIG. 8b by way of an incident ray 26^{vii}, which when passing through the lower optically effective surface 241, is broken in direction of the plumb line and traverses the body of the element 241, until it is again broken when exiting at the upper optically effective surface 242 formed by the respective facet 245 and reaches the opening 229 of the absorber pipe 228 as ray 215^{vii}.

As described with reference to FIG. 7b, the ray 206^{vii}, if it did not pass through an optical element, would reach the thermal opening 229 (broken line 246) had it not been offset in parallel as a result of being broken twice while passing through, which is indicated by the chain-dotted line 247 corresponding to FIG. 6b. In fact, the ray 206^{vii} is now broken at the inclined facet 245 such that the deviation is compensated for by the offset so that the ray 215^{vii} reaches the thermal opening 229.

Again, in practice the expert is able to determine the layout of the Fresnel grid structure (for example the size of the facets 245) and also the incline of each of the facets 245.

A further embodiment of an optical element configured as a Fresnel grid lens 250 is shown in FIG. 8c, wherein the lower and the upper optically effective surfaces 251, 252 are both provided with a Fresnel grid structure. Again the section through the Fresnel grid lens 250 corresponds to that of FIG. 3. Facets 256 in the lower surface 251 correspond to facets 255 in the upper surface 252, so that an incident reflected sun ray 206^{ix} impacts vertically upon the facets 256, 255 and is not broken by them, so that an aberration in the shown plane is stopped. Preferably the facets 255 in the upper surface 252 are then vertically inclined towards the plane in the figure (incline in direction 16) so that the rays 215^{ix} are concentrated in a focal point area at the location of the thermal opening 229. Here again a central zone 253, 254 is formed which is without facets 246, 255.

In practice the expert is able to determine the layout of the Fresnel grid structures and thus also the incline of each of the facets 255, 256.

FIG. 9 finally shows in form of a diagram a comparison between a conventional absorber pipe, which if seen in cross-section comprises a single wide thermal opening and an absorber arrangement/an absorber pipe as proposed here, i.e. comprising two adjacently arranged thermal openings according to FIG. 6b, for example.

A denotes the (larger) width of the thermal opening of the conventional absorber pipe, B denotes the width of each of the two thermal openings of the absorber pipe according to the invention (FIG. 6b). Both absorber pipes (i.e. the conventional one and the one according to the invention) may be associated with the same concentrator for the comparison, wherein the conventional absorber pipe with its thermal opening registers all focal line areas of the entire concentrator, whilst the thermal openings of the absorber pipe according to the invention are respectively associated with one half of this concentrator/the focal line area of this half.

The curves above the drawn widths A and B denote the power absorbed by the respective thermal openings via the concentrated radiation. The curve 320 shows the power absorbed by the conventional absorber pipe with one single thermal opening for the respective width A of this opening. Correspondingly the curves 321 and 322 show the power absorbed by the absorber pipe according to the invention via both their adjacent thermal openings.

The difference in the power absorbed by a conventional absorber pipe in relation to an absorber pipe according to the invention corresponds to the difference between the hatched surface and the two dotted surfaces in FIG. 9. The dotted surfaces are equal to or somewhat larger than the hatched area. Thus the power absorbed by the absorber pipe according to the invention with two less wide thermal openings is as great as or somewhat greater than that of the conventional absorber pipe with only one thermal opening.

This effect is due to the angle of aperture of the sun, according to which the radiation reflected in the concentrator of necessity gets scattered in a focal line area, which effect increases as the distance of the edge areas of the concentrator increases.

In summary the efficiency of the collector according to the invention can be further increased, as follows;

On the one hand the conventional thermal opening configured as a single elongated slot is dissolved in longitudinal direction into a number of smaller thermal openings, representing a total area of smaller openings which is smaller than the area of the single thermal opening. This is possible due to using a second concentrator arrangement which dissolves the focal line area of the trough concentrator into focal point areas.

Then the conventional thermal opening extending over the length of the absorber pipe is dissolved into thermal openings of lesser width which lie adjacent to each other when seen in cross-section, and each of the less wide openings is associated with a concentrator section. Thus for a smaller total area of thermal openings the heat input into the absorber pipe is the same as for a single thermal opening.

FIGS. 10a and 10b show a further embodiment of the present invention, in which the second concentrator arrangement does comprise, not a transparent optical element but a mirror. In FIG. 10a a solar collector 100 is shown, with a pressure cell 101 as known, mounted in a frame 102 which in turn is pivotably mounted on a base 103 for tracking the sun.

The pressure cell 101 has a first concentrator arrangement with a multipart concentrator consisting of sections 104 and 105 arranged in it, wherein, according to the invention, a two-part second concentrator arrangement is provided, comprising mirrors 106 and 107. Each mirror 106, 107 lies in the radiation path of the concentrator section 104, 105 associated with it. The incident solar radiation is represented by the rays 110, 111, the radiation path of the concentrator sections 104 and 105 by the reflected rays 112, 113. The mirrors 106, 107 lie in the radiation path upstream of the focal line area of the respective concentrator section 104, 105. The radiation path of the mirrors 106, 107 for the reflected solar radiation 112, 113 is represented by the radiation 114, 115 reflected at the mirrors. This reflected radiation 114, 115 is concentrated, according to the invention, by the mirrors 106, 107 in a focal point area 116 which lies in an associated opening of the absorber pipe.

The necessary curvature of the mirrors 106, 107 is schematically shown in FIG. 7b. Alternatively the mirrors 106, 107 may be provided with a Fresnel structure, especially preferably with a Fresnel grid structure. FIG. 7b represents a view upon part of the solar collector 100, wherein the direction of view approximately corresponds to the arrow direction for the reference symbol 100 in FIG. 7a. In order to aid understanding of the figure only the absorber pipe 120, one of the thermal openings 121 and a mirror 107 associated with this opening 121 are shown. Adjacent and similarly configured mirrors 107′ which are shown arranged in a row underneath the absorber pipe 120 across its entire length (arrow 16), are indicated by broken lines, wherein each mirror 107′ is associated in turn with an opening 121.

The mirror 107 is (concavely) curved in longitudinal direction 16 such that, seen in longitudinal direction, all incident rays 113 are concentrated upon the focal point area 116, and it is also additionally (concavely) curved in transverse direction so as to facilitate concentration upon the focal point area 116 in transverse direction.

FIG. 10c shows the arrangement of FIGS. 10a and 10b, wherein according to the invention means are provided for aligning the mirror 107 in an alignment area in relation to a current radiation path of the first concentrator arrangement. These means comprise a support 122 on which the mirrors 107 are pivotably mounted about a pivotal axis 123, wherein the pivotal movement is triggered by a lever 124 which is activated by a drive not shown in the figure in order to aid understanding.

Preferably the mirrors comprise a Fresnel grid structure which in practice the expert can determine in such a way that the desired success according to the invention is achieved. Mirrors of this kind may be manufactured as mouldings wherein for example the effective optical surface of the moulding may be given a suitable reflective coating.

The advantage of the arrangements shown in the figures is that the second concentrator arrangement may be arranged in the pressure cell of the first concentrator arrangement thereby protecting it against contamination. This in principle saves the considerable expenditure for cleaning when considering the fact that finely graduated Fresnel structures of the optical elements not protected by the pressure cell or Fresnel grid structures in the mirrors can be adequately cleaned only at a great deal of expense, which without this exorbitant cost would inevitably lead to losses in collector output.

In summary the present invention encompasses, in particular, the following points:

A. A solar collector with a first concentrator arrangement comprising a first radiation path with a focal line area for changing solar radiation incident upon it within an operating range and with an absorber arrangement for concentrated radiation, characterised by a second concentrator arrangement with at least one further concentrator arranged in the first radiation path upstream of its focal line area and for its part comprising a second radiation path with a focal point area, wherein the second concentrator arrangement comprises means for continuous alignment in an alignment area of the at least one further concentrator relative to a current radiation path of the first concentrator arrangement.

B. A solar collector according to point A, wherein the absorber element is configured as an absorber pipe and the second concentrator arrangement comprises at least one row of further concentrators arranged one behind the other over the length of the absorber pipe, and wherein at each location over the length of the absorber pipe at least one thermal opening is associated with the at least one further concentrator arranged there, and wherein preferably several rows of further concentrators are provided, and each further concentrator of each row is associated with a separate thermal opening, and wherein the means for continuous alignment of the further concentrators fixedly hold their focal point areas in the associated thermal opening.

These two points may encompass further embodiments according to the dependent claims.

1. A solar collector with a first concentrator arrangement comprising a first radiation path with a focal line area for changing solar radiation incident upon it within an operating range, and with an absorber arrangement for concentrated radiation, wherein the first concentrator arrangement comprises several concentrator sections each with a focal line area, and a second concentrator arrangement is provided with several rows of further concentrators arranged one behind the other over the length of the absorber arrangement, wherein the further concentrators of each row are respectively associated with a focal line area and are in the first radiation path upstream of the respective focal line area, and the further concentrators, on their part, comprises a second radiation path with one focal point area each, and wherein the collector comprises means for continuous alignment in an alignment area of the further concentrators relative to a current radiation path of the concentrator sections of the first concentrator arrangement, wherein over the length of the absorber arrangement each further concentrator of each row is associated with a thermal opening, which openings, on their part, are arranged on the absorber arrangement in adjacently extending rows, and wherein the means for continuous alignment of the further concentrators fixedly hold their focal point areas in the associated thermal opening.

2. The solar collector according to claim 1, wherein the absorber arrangement is configured as an absorber pipe, and the means for alignment are preferably provided in the second concentrator arrangement.

3. The solar collector according to claim 1, wherein the further concentrators in operation throw a shadow upon a space between two concentrator sections.

4. The solar collector according to claim 1, wherein two, preferably four, further preferably six, especially preferably eight concentrator sections are provided.

5. The solar collector according to claim 1, wherein photovoltaic cells are arranged in each thermal opening.

6. The solar collector according to claim 1, wherein the further concentrators are configured as optical elements transparent to solar radiation, which elements preferably comprise a Fresnel structure, especially preferably a Fresnel grid structure.

7. The solar collector according to claim 6, wherein the Fresnel lens comprises a Fresnel grid structure such that an offset of the passing-through ray is compensated for due to the thickness of the lens such that the ray reaches the thermal opening despite the offset.

8. The solar collector according to claim 1, wherein the further concentrators comprise mirrors which reflect the radiation into a focal point area.

9. The solar collector according to claim 1, wherein the second radiation path between a further concentrator and its focal point area is delimited by delimiting minors arranged laterally in the radiation path, which mirrors comprise a third radiation path for radiation concentrated by the at least one further concentrator, preferably with a focal point area situated at the location of the focal point area of the second radiation path.

10. The solar collector according to claim 9, wherein the delimiting mirrors comprise a compound parabolic concentrator.

11. The solar collector according to claim 1, wherein the thermal openings are arranged in several rows extending in parallel with each other along the length of the absorber arrangement, and wherein the thermal openings of each row are grouped adjacent to each other preferably level with the height of the absorber pipe and are arranged group for group one behind the other along the length of the absorber pipe.

12. The solar collector according to claim 1, wherein the thermal openings are arranged in two, preferably in four, further preferably in six and especially preferably in eight rows.

13. The solar collector according to claim 11, wherein the absorber arrangement preferably configured as an absorber pipe is externally insulated all the way round including the areas between the thermal openings.

14. The solar collector according to claim 1, wherein the further concentrators of the second concentrator arrangement are connected with a carrier arrangement preferably pivotably arranged on the absorber element and wherein the pivotal axis preferably lies in the focal point area of the further concentrator.
